(19) United States
(12) Patent Application Publication
(10) Pub. No.: US 2025/0160507 A1
(43) Pub. Date: May 22, 2025

(54) Cylindrical Brush with Varying Brush Nodule Length

(71) Applicant: Tech Core PVA, LLC, Rocklin, CA (US)

(72) Inventors: Briant Benson, Placerville, CA (US); Michael Dobbins, Newcastle, CA (US); Maxim Nesmiyan, Antelope, CA (US); Brian Cooper, Citrus Heights, CA (US); David Ottman, Carmichael, CA (US)

(21) Appl. No.: 18/956,699

(22) Filed: Nov. 22, 2024

Related U.S. Application Data
(60) Provisional application No. 63/602,306, filed on Nov. 22, 2023.

(51) Int. Cl. A46B 9/12; A46B 7/00; A46B 9/02; A46D 1/00; H01L 21/67

(52) U.S. Cl. CPC A46B 9/12; A46B 7/00; A46B 9/026; A46D 1/0207; H01L 21/67046; A46B 2200/3073

(57) ABSTRACT

The present invention provides a cylindrical brush assembly designed for precision cleaning of circular wafers and delicate surfaces. The brush features polyvinyl alcohol (PVA) nodules of varying lengths along one side of a cylindrical core, enabling conformity to changing gap sizes when applied at an angle to the wafer. This ensures consistent contact and uniform cleaning across the entire surface. A modular design with replaceable nodule holders allows for easy customization and maintenance. An integrated RFID tracking system embedded in the end cap monitors usage and wear levels in real time. The cleaning method involves rotating the brush at an angle relative to the wafer surface, with the nodules adapting to surface contours for optimal efficiency. While tailored for semiconductor wafer cleaning, the assembly is adaptable for other industrial applications requiring precision cleaning.

### PRIORITY INFORMATION

The present application claims priority to United Provisional Patent Application No. 63/602,306 filed Nov. 22, 2023, the contents of which are incorporated herein as if set out in full.

### BACKGROUND OF THE DISCLOSURE

### Technical Field of the Disclosure

The present invention relates generally to cleaning tools and methods for manufacturing such tools, specifically cylindrical brushes used to clean electronic components, such as wafers. The invention improves on conventional brush designs by employing nodules of varying lengths, which allow for better contact with the wafer surface, particularly when applied at an angle, improving efficiency and reducing material use.

### Background and Description of the Related Art

The production of electronic components, especially silicon wafers, involves multiple stages of processing where surface cleanliness is of utmost importance. Any particulate matter or residue left on the surface can lead to defects in the final product. As such, specialized cleaning tools, like cylindrical brushes, have been widely employed to scrub and rinse the surfaces of wafers during various stages of production. Cylindrical brushes are commonly used as part of this production process. In particular, with respect to a step of the manufacturing process of the electronic components such as silicon wafers, the components are cleaned with specialized brushes. One such type of brush comprises bristles of cured polyvinyl alcohol (PVA), or polyvinyl formalin.

PVA is the key polymeric component in a solution that when poured into a mold and heated, forms a tough sponge-like material called polyvinyl formalin, or otherwise known as cured PVA. The PVA solution comprises PVA crystal, formaldehyde, sulfuric acid, deionized water, and potato starch.

Conventional Cleaning Brushes: Cylindrical brushes are a common solution in the semiconductor industry for cleaning wafers. These brushes are typically mounted on shafts and rotate to scrub the surface of the wafers. The most commonly used brushes are made of polyvinyl alcohol (PVA), a material valued for its ability to hold moisture and cleaning agents while maintaining a soft, non-abrasive texture.

One such conventional brush is brush 12 as shown in FIGS. 1A and 1B wherein a plurality of bristles 16 but also the majority of a core member 14 are made up of the polyvinyl formalin material. Here, the bristles are round nodules. As a component of a cleaning system 10, the brush 12 may be mounted to a shaft (not shown) by sliding the shaft through the keyed center hole. The shaft and its tight fitment provide further rigidity to the brush 12. As the entire assembly is spun about an axis running the length center of the cylinder, it is pressed against the surface of the object to be cleaned, and the cleaning chemical is applied via physical contact from the brushes 12. During this process, torque is generated on the brush 12 opposite the direction of rotation. The conventional cleaning brushes include the presence of toxic materials in the form of the PVA.

A typical cylindrical brush has uniformly spaced and equally long nodules or bristles, arranged symmetrically around a cylindrical core. As the brush rotates, the nodules come into contact with the wafer, cleaning its surface. The wafers, often spinning in tandem with the brush, rely on the mechanical action of the brush to dislodge and remove contaminants.

Challenges in Prior Art: While these brushes have become standard in wafer cleaning, they have several significant limitations:

Uniform Nodule Length: Most conventional brushes feature nodules of equal length. This uniformity creates problems when the brush is applied at an angle or in situations where the surface of the object being cleaned is not flat or consistent. For instance, cleaning wafers often requires the brush to make angled contact to ensure coverage. However, uniform nodules fail to accommodate the varying gap sizes that result from angled contact, leading to inefficient cleaning.

Limited Flexibility and Adaptability: In many cleaning applications, it is necessary to adjust the brush's configuration based on the size and shape of the object. Brushes with fixed, uniform nodules lack flexibility, making it difficult to clean effectively when the brush angle or the wafer dimensions vary. This leads to inconsistent cleaning results, particularly when the brush is required to clean at different angles or on varying surfaces.

Material Inefficiency: Conventional brush designs use significant amounts of PVA material, which increases manufacturing costs and the overall weight of the brush. The excessive use of PVA, combined with the uniform nodule design, results in more material being used than is necessary for efficient cleaning. Additionally, the added weight places more strain on the machinery, leading to increased wear and tear over time.

Contamination Risks: During the cleaning process, brushes made from PVA or other materials can degrade, releasing small particles that can re-contaminate the surface being cleaned. Traditional brush designs have not adequately addressed this issue, resulting in brushes that contribute to, rather than reduce, contamination over time.

There have been previous advancements to attempt to overcome these challenges described above.

Brush Manufacturing Methods: The typical method of manufacturing cylindrical brushes involves molding PVA into uniform bristle shapes that are then attached to the cylindrical core. Advances have been made to speed up the production process, reduce curing time, and improve the integration of the PVA bristles with the core. However, these methods still fail to offer solutions to the core problem of inefficiency when cleaning at angles or non-flat surfaces.

Despite the various advancements in materials and brush design, there remain several key issues in current technologies:

Poor Adaptation to Angled Cleaning: Uniform nodule lengths mean that brushes cannot adjust effectively to the gap variations created when the brush is applied at an angle to the wafer's surface. This leads to uneven pressure distribution and inconsistent cleaning performance.

Excessive Use of PVA Material: Most current brush designs use more PVA material than necessary, resulting in higher costs, heavier brushes, and greater environmental impact due to the production of toxic chemicals during the PVA curing process.

Limited Customization: While there are some attempts to adjust brush stiffness or nodule softness, the general approach has remained the same—relying on uniform nodule shapes and lengths. This significantly limits the ability to customize brushes for specific cleaning tasks, such as cleaning wafers of different sizes or shapes.

In some industries wafers are cleaned using two brushes as shown in FIG. 21. Here, the two brushes come into contact with the wafer only on one side such that their own spinning action is impart to the wafer, which then spins on its own axis as shown.

### SUMMARY OF THE INVENTION

To minimize the limitations found in the prior art, and to minimize other limitations that will be apparent upon the reading of the specification, the present disclosure provides a cylindrical brush that is specifically designed to overcome the limitations of traditional wafer cleaning tools. The brush features variable nodule lengths along one side, enhancing its ability to clean electronic components such as wafers, especially when the brush is applied at an angle. This design improves contact consistency with the wafer, reduces material usage, and enhances the cleaning efficiency, particularly in semiconductor manufacturing processes where precision is critical.

The preferred embodiment may also include a method for manufacturing the cylindrical brush. The method commences by creating a molding assembly. In the preferred method, at least one of a plurality of rail plates is positioned on a foam-fitting recess of a first plate having a plurality of first plate holes. The at least one of the plurality of rail plates is slotted firmly for positioning into the foam-fitting recess that provides a tight friction fit which prevents the leakage of polyvinyl alcohol (PVA) once the PVA solution is introduced at a later step of the preferred method. Each rail plate includes a plurality of rail holes. Next, the at least one of the plurality of rail plates aligned with the first plate is positioned on a second plate having a plurality of second plate holes. The plurality of second plate holes is aligned with the plurality of rail holes such that the rail plate is fairly precise fit with the second plate. The first plate and the second plate effectively sandwich the rail plate snugly inside an internal cavity of the rail plate.

The second plate has large holes to form a plurality of PVA nodules. The second plate aligned with the at least one rail plate is placed on a seal plate. The seal plate closes the second plate holes thereby preventing these holes from being exposed to open air. The only openings to open air at this point are from an upper portion of the first plate.

A top plate having a plurality of top plate holes is placed on the first plate. The plurality of top plate holes is aligned with the first plate holes thereby creating the molding assembly. Next, the molding assembly is locked utilizing at least one locking member. The locking member is selected from a group consisting of tape, clamps, or bolts and nuts.

Then, PVA is mixed into a PVA gel. The PVA gel is injected into each of the plurality of top plate holes of the top plate utilizing an injection device such as a syringe or similar suitable device. The PVA gel seeps down through at least one of the plurality of second plate holes to create at least one of the plurality of PVA nodules. Thereafter, the PVA gel overflows and begins to fill the internal cavity of the at least one of the plurality of rail plates. Each successive second plate hole that is filled with the PVA gel makes another PVA nodule and helps to fill the internal rail plate. In this way, the plurality of PVA nodules is created at the second plate.

Next, the molding assembly is placed into a heating apparatus such as an oven. The heating apparatus cures the plurality of PVA nodules and converts the PVA gel in the plurality of PVA nodules into a PVA sponge material thereby creating at least one of a plurality of PVA nodule foam bars. The at least one locking member is removed from the molding assembly. The PVA gel that is cured on the top plate is peeled off thereby removing a portion of pegs of the PVA sponge material that now extends down into a shaft of a core member of the cleaning tool. The first plate is removed and the remaining pegs of the PVA sponge material is peeled off.

Next, the seal plate is removed thereby providing full access to the PVA nodule faces. The removal of the seal plate facilitates the removal of the at least one of the plurality of PVA nodule foam bars having a row of PVA nodules (and, by extension, the rail plate) by poking the PVA nodules through the second plate holes. This prevents damage to the PVA nodules. If there was only one plate in the mold that created the PVA nodules, which then needed the rail plate to be pulled out, the PVA nodules would tear. This is the reason why the seal plate separates to allow the PVA nodules to be pushed out instead of pulled. In this way, the molding process for the rail plate is completed.

In order to create the cleaning tool, the plurality of PVA nodule foam bars must be attached to the core member. For this, the plurality of rail plates is inserted along an outer wall of the core member of the cleaning tool in a unique pattern that allows the plurality of PVA nodules to clean the electronic components efficiently. The unique pattern includes an alternate arrangement of the plurality of rail plates along the outer wall of the core member. Each of the plurality of PVA nodule foam bars is installed at each of the plurality of rail plates thereby creating the cleaning brush. The core member includes a pair of openings that is closed utilizing a pair of end caps.

### Key Aspects of the Invention

Varying Nodule Lengths for Enhanced Cleaning Performance: One of the key innovations of the invention is the use of variable nodule lengths along one side of the cylindrical brush. Unlike conventional brushes with uniform nodules, the present invention allows the brush to conform to changing gap sizes between the wafer surface and the brush when applied at various angles. This enables better surface coverage and ensures that the nodules make consistent contact with the wafer, improving cleaning performance and reducing the risk of contamination.

Optimal Angle Cleaning: The invention is particularly beneficial when the brush is applied at an angle to a circular wafer. By varying the lengths of the nodules, the brush can adapt to the changing distances between the brush surface and the wafer, ensuring that even the farthest-reaching nodules can effectively scrub the wafer. This reduces the need for repositioning and enhances cleaning efficiency across the entire surface of the wafer.

Reduced Material Usage and Environmental Impact: A key objective of the invention is to reduce the amount of polyvinyl alcohol (PVA) or similar materials used in the brush. By employing a more strategic arrangement of nodules, where lengths vary based on the cleaning requirements, the present invention uses significantly less material than traditional brushes.

This reduction in material provides multiple benefits, such as lower production costs and raw material use, reduction in overweight of the brush, which reduces the strain on machinery and results in less wear and tear on equipment, and finally environmental benefits because through the use of less PVA and toxic chemicals in the manufacturing process.

Adaptability to Different Wafer Sizes and Shapes: The invention's design is adaptable to different wafer sizes and shapes, providing greater flexibility for various cleaning applications. Traditional brushes with uniform nodules are generally limited in their ability to adapt to various wafer configurations, but the present invention allows for customizable nodule configurations that can be tailored to the specific needs of different wafers or other electronic components.

Customization Options: The nodule lengths and densities can be adjusted depending on the surface characteristics of the wafer or the angle at which the brush will be used. This adaptability makes the brush suitable for a range of applications in semiconductor manufacturing and other industries where precision cleaning is required.

Improved Cleaning Efficiency and Contamination Reduction: The varying nodule lengths allow the brush to apply consistent pressure across the wafer's surface, ensuring that all areas are cleaned effectively. This prevents certain areas from being over-scrubbed while others are insufficiently cleaned, a common problem with brushes that have uniform nodules.

Reduced Particle Contamination: Because the brush maintains better contact with the wafer surface, fewer particles are left behind during cleaning. This is crucial in semiconductor manufacturing, where even the smallest particles can cause defects in the final product.

Innovative Nodule Design and Manufacturing Process: The manufacturing process for the cylindrical brush includes forming the nodules through a specialized molding process that allows for precise control over the length and shape of each nodule. The nodules are then attached to the core of the brush in a strategic pattern to maximize cleaning efficiency.

Molding Process: The brush is produced by injecting PVA gel into a specially designed mold that accommodates the varying lengths of the nodules. The gel is cured to form a sponge-like material that retains cleaning agents while maintaining flexibility for effective cleaning.

Rail Plate Assembly: The nodules are mounted on rail plates, which are then secured to the cylindrical core of the brush. This ensures that the nodules are securely fastened, preventing dislodgement during high-speed rotation in cleaning machines.

Design for Use with Automated Manufacturing Systems: The cylindrical brush is designed to be compatible with fully automated manufacturing processes, allowing for high production yields with minimal manual intervention. The brush assembly, which includes the nodule molding and attachment to the core, is optimized for automation, reducing production times and costs.

High Production Yields: The automated process increases efficiency in production, with fewer defects and less downtime for mold cleaning and maintenance. This makes the brush an attractive option for high-volume manufacturing environments.

Shorter Curing Times: The PVA gel used in the nodules cures quickly, further speeding up the production process and reducing energy consumption in the manufacturing facility.

Reduction in Wear on Machinery: By reducing the overall weight of the brush, the invention minimizes the wear and tear on the cleaning machinery. Lighter brushes exert less force on the rotating motors and bearings, leading to longer machine life and lower maintenance costs.

RFID Integration for Monitoring and Tracking: In some optional embodiments, the brush includes an RFID tag embedded in the drive cap. This feature allows for real-time monitoring and tracking of the brush during the cleaning process, enabling better quality control and maintenance scheduling. The RFID tag provides important data such as the number of uses, cleaning cycles, and operational conditions, which helps optimize brush performance over its lifespan.

It is a first objective of the invention to provide a cylindrical brush with varying nodule lengths and to provide a method for manufacturing a cylindrical brush of a cleaning tool for cleaning electronic components:

It is a second objective of the invention to provide improved cleaning efficiency because the varying nodule lengths provide better surface contact, especially when the brush is applied at an angle, resulting in more thorough cleaning of the wafer surface.

It is a third objective of the invention to reduce material usage, because the design uses less PVA, lowering production costs and environmental impact while maintaining high cleaning standards.

It is another objective of the present invention is to provide a cylindrical brush manufactured requiring less curing time.

It is another objective of the invention to provide versatility, as the brush can be adapted to different wafer sizes and cleaning angles, making it suitable for various applications.

It is yet another objective of the invention to provide contamination control, since the brush releases fewer particles during cleaning, reducing the risk of re-contaminating the wafer.

It is yet another objective of the present invention to product a brush having uneven brush lengths such that the brush evenly touches a wafer across one side of the wafer thus imparting a spin to the wafer.

It is yet another objective of the invention to provide a brush with increased durability and reduced maintenance, as the brush's design reduces wear on cleaning machinery and allows for longer machine life with lower maintenance costs.

It is yet another objective of the present invention to provide a cylindrical brush and a core which are mechanically unified to prevent slippage between the brush and the core and to maintain same rotational velocity in the brush as present in the core.

It is yet another objective of the present invention is to provide a cylindrical brush featuring a unique pattern of a plurality of rail plates along an outer wall of a core member that allows the plurality of PVA nodules to clean electronic components efficiently.

It is another objective of the invention to automate the production method, ensuring high production yields and reducing the time and labor required for brush assembly.

These and other advantages and features of the present invention are described with specificity so as to make the present invention understandable to one of ordinary skill in the art.

### BRIEF DESCRIPTION OF THE DRAWINGS

Elements in the figures have not necessarily been drawn to scale in order to enhance their clarity and improve understanding of these various elements and embodiments of the invention. Furthermore, elements that are known to be common and well understood to those in the industry are not depicted in order to provide a clear view of the various embodiments of the invention. Thus, the drawings are generalized in form in the interest of clarity and conciseness.

FIG. 1A and FIG. 1B show perspective views of an existing type of a cylindrical brush having round nodules;

FIG. 2 shows a front perspective view of a cylindrical brush of a cleaning tool in accordance with the preferred embodiment of the present invention;

FIG. 3 shows a perspective view of the cylindrical brush having an end portion in an open state in accordance with the preferred embodiment of the present invention;

FIG. 4A and FIG. 4B show perspective views of a molding assembly of the cylindrical brush in accordance with the preferred embodiment of the present invention;

FIG. 4C is a cross-sectional view of the molding assembly shown in FIG. 4B in accordance with the preferred embodiment of the present invention;

FIG. 5A shows a perspective view of a plurality of polyvinyl alcohol (PVA) nodules at a rail plate of the cylindrical brush in accordance with the preferred embodiment of the present invention;

FIG. 5B shows a cross-sectional view of the rail plate mounted with the plurality of PVA nodules in accordance with the preferred embodiment of the present invention;

FIG. 5C shows a perspective view of the rail plate without a PVA nodule foam bar inserted therethrough in accordance with the preferred embodiment of the present invention;

FIG. 5D shows a perspective view of the PVA nodule foam bar in accordance with the preferred embodiment of the present invention;

FIG. 5E and FIG. 5F show perspective views of a rail top portion and a rail bottom portion respectively in accordance with the preferred embodiment of the present invention;

FIGS. 5G-5I show perspective views of mating registration features of a plurality of rail plates and a pair of end caps in accordance with the preferred embodiment of the present invention;

FIG. 6 shows a perspective view of the PVA nodule foam bar of the cylindrical brush in accordance with the preferred embodiment of the present invention;

FIG. 7 shows a perspective view of the rail plate illustrated without the PVA nodule foam bar in accordance with the preferred embodiment of the present invention;

FIG. 8 shows a perspective view of the rail plate in a complete assembled state in accordance with the preferred embodiment of the present invention;

FIG. 9 shows a perspective view of a core member of the cleaning tool in accordance with the preferred embodiment of the present invention;

FIG. 10 shows a perspective view of the core member of the cleaning tool with portions of the rail plate inserted thereon and into which a row of PVA nodules being inserted in accordance with the preferred embodiment of the present invention;

FIG. 11A shows a perspective view of the complete assembly of the cleaning tool illustrating the cylindrical brush and the plurality of PVA foam bars in accordance with the preferred embodiment of the present invention;

FIG. 11B shows a top view of the cleaning tool shown in FIG. 11A in accordance with the preferred embodiment of the present invention;

FIG. 11C shows a rear view of the cleaning tool shown in FIG. 11A in accordance with the preferred embodiment of the present invention;

FIG. 12 shows an exploded view of another embodiment of the cylindrical brush illustrating a holder attached to a core member for holding a PVA nodule in accordance with one embodiment of the present invention;

FIG. 13 shows a perspective view of the fully assembled cylindrical brush illustrated in FIG. 12 in accordance with one embodiment of the present invention;

FIG. 14 shows a rear view of the cylindrical brush illustrated in FIG. 12 without end caps in accordance with one embodiment of the present invention;

FIG. 15 shows an exploded view of the cylindrical brush illustrated in FIG. 12 in accordance with one embodiment of the present invention;

FIG. 16 shows a perspective view of another embodiment of a holder and a PVA nodule of a cylindrical brush in accordance with one embodiment of the present invention;

FIG. 17 shows an RFID embedded in the cap of the device;

FIG. 18 shows a standard brush layout where the nodules are spaced evenly from end to end longitudinally down the brush; and

FIG. 19 shows a configuration wherein the nodules are not spaced evenly from end to end longitudinally down the brush.

FIG. 21 shows a prior art image of two brushes cleaning a wafer and imparting their respective spins to the wafer.

### DETAILED DESCRIPTION OF THE DRAWINGS

In the following discussion that addresses a number of embodiments and applications of the present invention, reference is made to the accompanying drawings that form a part hereof, and in which is shown by way of illustration specific embodiments in which the invention may be practiced. It is to be understood that other embodiments may be utilized, and changes may be made without departing from the scope of the present invention.

Various inventive features are described below that can each be used independently of one another or in combination with other features. However, any single inventive feature may not address any of the problems discussed above or only address one of the problems discussed above. Further, one or more of the problems discussed above may not be fully addressed by any of the features described below.

As used herein, the singular forms “a”, “an” and “the” include plural referents unless the context clearly dictates otherwise. “And” as used herein is interchangeably used with “or” unless expressly stated otherwise. As used herein, the term ‘about” means +/−5% of the recited parameter. All embodiments of any aspect of the invention can be used in combination, unless the context clearly dictates otherwise.

Unless the context clearly requires otherwise, throughout the description and the claims, the words ‘comprise’, ‘comprising’, and the like are to be construed in an inclusive sense as opposed to an exclusive or exhaustive sense; that is to say, in the sense of “including, but not limited to”. Words using the singular or plural number also include the plural and singular number, respectively. Additionally, the words “herein,” “wherein”, “whereas” “above,” and “below” and words of similar import, when used in this application, shall refer to this application as a whole and not to any particular portions of the application.

The description of embodiments of the disclosure is not intended to be exhaustive or to limit the disclosure to the precise form disclosed. While the specific embodiments of, and examples for, the disclosure are described herein for illustrative purposes, various equivalent modifications are possible within the scope of the disclosure, as those skilled in the relevant art will recognize.

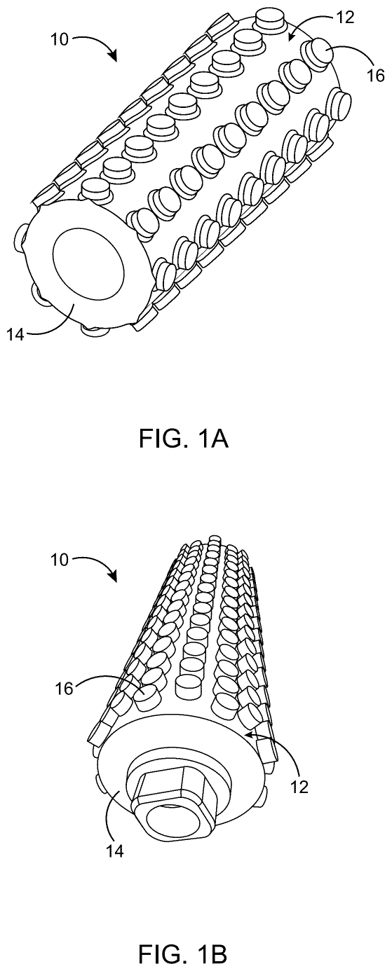

FIGS. 1A and 1B illustrate perspective views of a prior art cylindrical brush with uniform, round nodules. These figures depict the typical design used in wafer cleaning processes where cylindrical brushes are mounted on a rotating shaft. The nodules are made from polyvinyl alcohol (PVA), forming a soft, sponge-like structure ideal for cleaning delicate surfaces like wafers.

FIG. 1A: Shows a perspective view of a cylindrical brush with PVA nodules evenly distributed around the core. This standard configuration is designed to scrub the surface of wafers but has limitations when applied at an angle due to the uniform length of the nodules. FIG. 1B: Provides a side perspective view, highlighting the uniform length of the nodules. This design often leads to uneven cleaning when the brush is applied to circular wafers at varying angles. The figures emphasize the shortcomings of conventional brushes, which lack adaptability to different gap sizes when applied to angled surfaces, leading to inefficient cleaning.

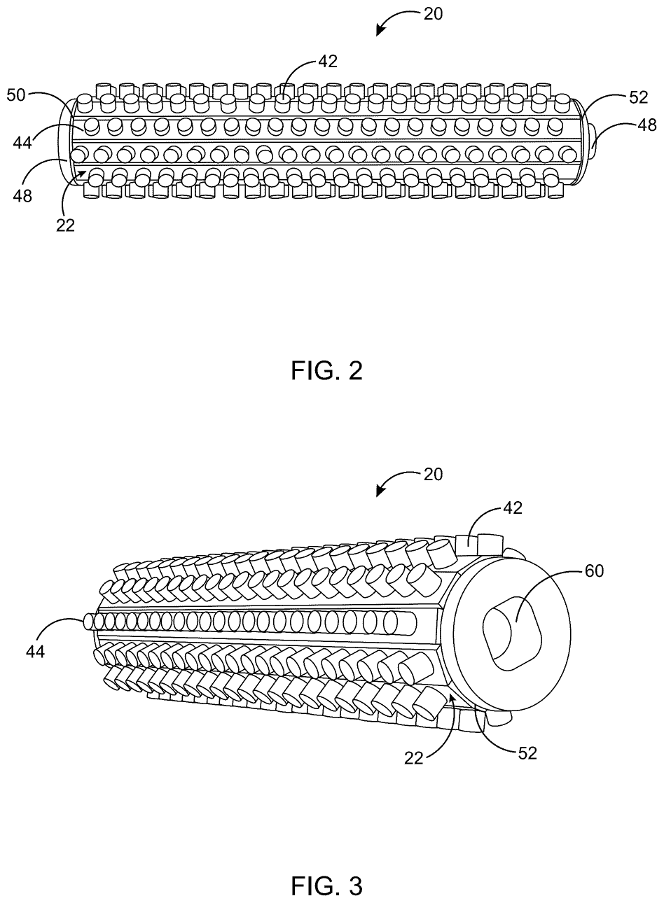

FIG. 2 shows a front perspective view of the cylindrical brush according to the present invention, highlighting its unique design with varying nodule lengths. This innovation addresses the limitations seen in the prior art by allowing for more effective cleaning at various angles, particularly when used on circular wafers.

The brush consists of a core member with polyvinyl alcohol (PVA) nodules attached to the outer surface using rail plates. The nodules are of varying lengths, arranged strategically along one side of the brush, to ensure efficient cleaning even when the brush is positioned at an angle. The alternating nodule lengths provide greater surface contact with the wafer, allowing the brush to accommodate changing gap sizes and apply consistent pressure across the wafer's surface. This figure demonstrates the key improvement in the invention, where the brush's adaptability to angled surfaces ensures more effective and uniform cleaning.

FIG. 3 illustrates a perspective view of the cylindrical brush with an open end portion, showing the internal structure and how the PVA nodules are secured to the core. The brush's core member is shown in detail, revealing how the PVA nodule foam bars are mounted onto the rail plates that are affixed to the core. The open end portion of the brush reveals the core's internal configuration, which includes keyed sections designed to ensure proper alignment and attachment of the rail plates and foam bars. This design ensures that the brush nodules are securely affixed to the core, preventing dislodgement during high-speed rotations that occur during the wafer cleaning process. The figure highlights the brush's structural integrity, ensuring that the varying-length nodules remain firmly in place for consistent and effective cleaning.

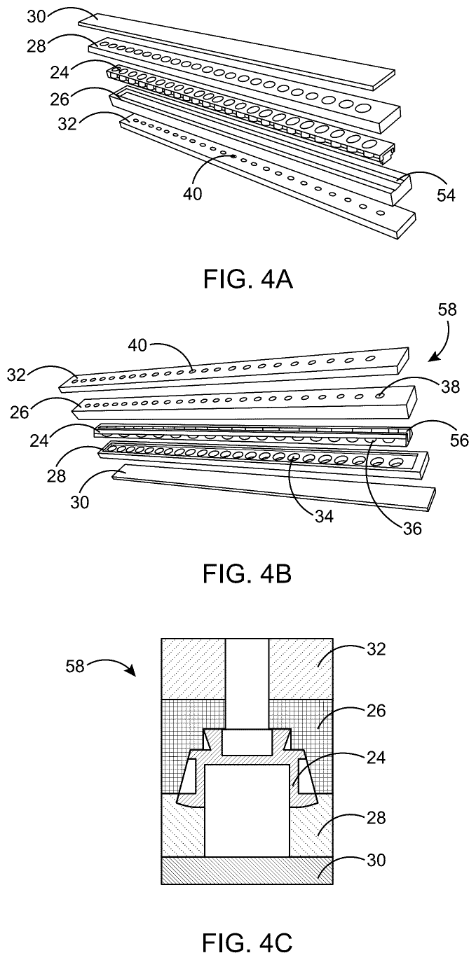

Continuing with FIGS. 2 and 3, a cylindrical brush 22 of a cleaning tool 20 for cleaning electronic components is illustrated. The preferred embodiment describes a method for manufacturing the cylindrical brush 22 clearly illustrated in FIGS. 4A-4C. The method commences by creating a molding assembly 58. For creating the molding assembly 58, at least one of a plurality of rail plates 24 is positioned on a foam-fitting recess 54 of a first plate 26 having a plurality of first plate holes 38 as shown in FIGS. 4A and 4B. The at least one of the plurality of rail plates 24 is slotted firmly for positioning into the foam-fitting recess 54 and provides a tight friction fit that prevents PVA leaking once the PVA solution is introduced at a later step of the preferred method. Each rail plate 24 includes a plurality of rail holes 36. Next, the at least one of the plurality of rail plates 24 aligned with the first plate 26 is positioned on a second plate 28 having a plurality of second plate holes 34 as shown in FIG. 4B. The plurality of second plate holes 34 is aligned to the plurality of rail holes 36 such that the rail plate 24 is fairly precise fit with the second plate 28. The first plate 26 and the second plate 28 effectively sandwich the rail plate 24 snugly inside an internal cavity 56 of the rail plate 24.

FIGS. 4A through 4C provide detailed views of the molding assembly used to create the PVA nodules and rail plates, which are integral to the cylindrical brush's construction. FIG. 4A: Shows a perspective view of the first plate of the molding assembly, which includes a series of holes designed to accommodate the polyvinyl alcohol (PVA) gel during the molding process. The rail plate is positioned in a foam-fitting recess on this plate, ensuring a tight fit to prevent leakage during the PVA injection process. FIG. 4B: Illustrates how the second plate is positioned over the first plate. The second plate has corresponding holes that align with those on the first plate, allowing the PVA gel to flow through and form the nodules. The plates are sandwiched together with the rail plate in between, creating a secure internal cavity for molding the PVA nodules. FIG. 4C: Presents a cross-sectional view of the molding assembly, showing how the PVA gel is injected into the top plate and flows down through the aligned holes of the first and second plates to form the nodules. The seal plate at the bottom prevents the gel from escaping, ensuring that the PVA nodules are properly molded and cured.

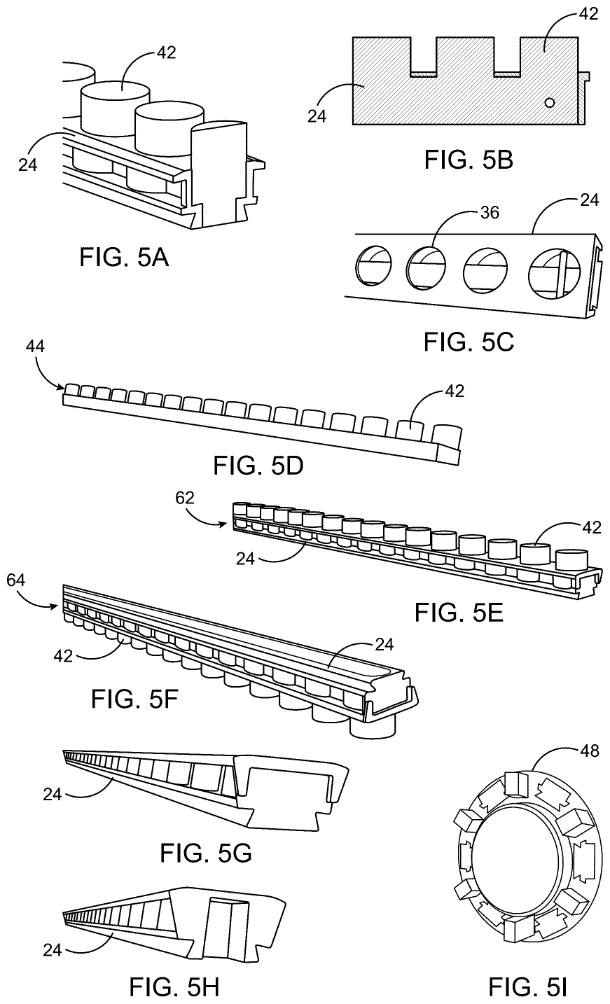

The second plate 28 has large holes to form a plurality of PVA nodules 42 (see FIG. 5A). As shown in FIG. 4B, the second plate 28 aligned with the at least one rail plate 24 is placed on a seal plate 30. The seal plate 30 closes the second plate holes 34 thereby preventing these holes 34 from being exposed to open air. The only openings to open air at this point are from an upper portion of the first plate 26.

A top plate 32 having a plurality of top plate holes 40 is placed on the first plate 26 as shown in FIG. 4B. The plurality of top plate holes 40 is aligned with the first plate holes 38 thereby creating the molding assembly 58. FIG. 4C shows a cross-sectional view of the molding assembly 58. Next, the molding assembly 58 is locked utilizing at least one locking member (not shown). The locking member is selected from a group consisting of tape, clamps, or bolts and nuts.

Then, polyvinyl alcohol (PVA) is mixed into a PVA gel. The PVA gel is injected into each of the plurality of top plate holes 40 at the top plate 32 utilizing an injection device such as a syringe or similar suitable device. The PVA gel seeps down through at least one of the plurality of second plate holes 34 to create at least one of the plurality of PVA nodules 42 (see FIG. 5A). Thereafter, the PVA gel overflows and begins to fill the internal cavity 56 of the at least one of the plurality of rail plates 24. Each successive second plate hole 34 that is filled makes another PVA nodule 42 and helps to fill the internal cavity 56. In this way, the plurality of PVA nodules 42 is created at the second plate 28.

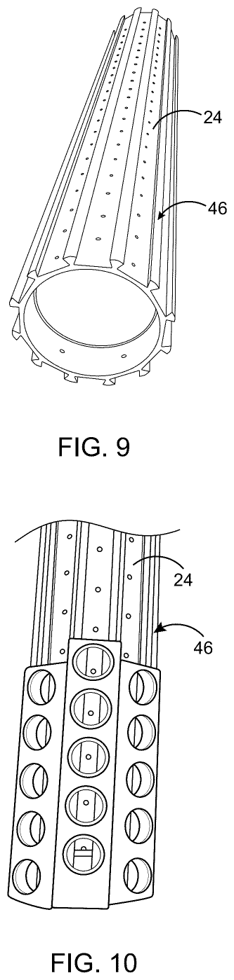

Next, the molding assembly 58 is placed into a heating apparatus such as an oven. The heating apparatus cures the plurality of PVA nodules 42 and converts the PVA gel in the plurality of PVA nodules 42 into a PVA sponge material thereby creating at least one of a plurality of PVA nodule foam bars 44 (see FIG. 5D). The at least one locking member is removed from the molding assembly 58. The PVA gel that is cured on the top plate 32 is peeled off thereby removing a portion of pegs of the PVA sponge material that now extends down into a shaft of a core member 46 (see FIG. 9) of the cleaning tool 20. The first plate 26 is removed and the remaining pegs of the PVA sponge material is peeled off.

Thereafter, the seal plate 30 is removed thereby providing full access to the PVA nodule faces 42. The removal of the seal plate 30 facilitates the removal of the at least one of the plurality of PVA nodule foam bars 44 having a row of PVA nodules 42 (and, by extension, the rail) by poking the PVA nodules 42 through the second plate holes 34 as shown in FIG. 5D. This prevents damage to the PVA nodules 42. If there was only one plate in the molding assembly 58 that created the PVA nodules 42, which then needed the rail plate 24 to be pulled out, the PVA nodules 42 would tear. This is the reason why the seal plate 30 separates to allow the PVA nodules 42 to be pushed out instead of pulled. In this way, the molding process is completed.

In order to create the cleaning brush 22, the plurality of PVA nodule foam bars 44 must be attached to the core member 46 (see FIG. 9). For this, the plurality of rail plates 24 is inserted along an outer wall of a core member 46 of the cleaning tool 20 in a unique pattern. Each of the plurality of PVA nodule foam bars 44 is installed at each of the plurality of rail plates 24. The core member 46 includes a pair of openings 60 (see FIG. 3) that is closed utilizing a pair of end caps 48 (see FIG. 2). The unique pattern includes an alternate arrangement of the plurality of rail plates 24 along the outer wall of the core member 46. This alternate arrangement allows the plurality of PVA nodules 42 to clean electronic components efficiently.

FIG. 5A shows a perspective view of the PVA nodules 42 mounted on a rail plate 24. The nodules are of varying lengths, arranged strategically along the plate to ensure optimal cleaning performance. The rail plate itself includes a series of holes that securely hold the nodules in place. FIG. 5B shows a cross-sectional view of the rail plate 24 mounted with the plurality of PVA nodules. This figure shows the tight fit between the nodules and the rail plate, ensuring that the nodules remain securely in place during use.

In the preferred embodiment, the wall thickness of the plastic housing PVA nodule 42 is a consistent 1 mm all around, although various thicknesses may be used as well. This 1 mm wall is to minimize differing contraction rates of varying wall thicknesses during the plastic injection molding process. This is why the side walls are foam-fitting to the PVA nodules 42 in the body.

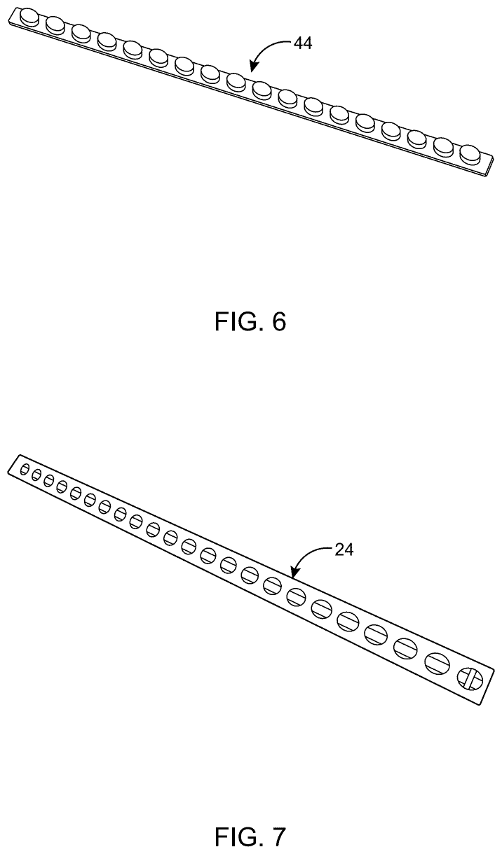

Referring to FIG. 5C and FIG. 7, the rail plate 24 is shown without the PVA nodule foam bar 44 inserted therethrough, showing the configuration of the plate's holes designed to hold the nodules. FIG. 5D displays a perspective view of the PVA nodule foam bar outside of the rail plate. This figure shows how the nodules are connected as part of a continuous foam bar 44, which is inserted into the rail plate 24 during assembly and which connects all the PVA nodules 42 into a single piece. This single-piece design prevents any PVA nodule 42 from becoming dislodged. This single row of nodules 44 is shown in FIG. 6.

FIG. 5E and FIG. 5F show close-up views of the top and bottom portions of the rail plate, illustrating the precise engineering involved in the plate's design to hold the nodules securely. Specifically, a rail top portion 62 and rail bottom portion 64 of the assembled rail plate 24 respectively are shown. FIGS. 5G-5I show mating registration features of the plurality of rail plates 24 and the pair of end caps 48 of the full assembly. These features exist to ensure that the rail plates are properly aligned and securely fastened to the core member, preventing misalignment during the brush's operation to ensure assemblers cannot assemble the cylindrical brush 22 without alternating directions of each rail plate 24 in sequence. The alternating nature or pattern creates a zig-zag arrangement of the PVA nodules 42 on the brush 22 for proper cleaning performance. As shown in FIG. 5G, the keyed endcap not only secures the rail plate 24 in place along the core member 46 but also keys the rail plate 24 so that each rail plate 24 is positioned in the proper location along the core member 46.

FIG. 6 provides a perspective view of the PVA nodule foam bar used in the cylindrical brush. This figure highlights the structure and configuration of the foam bar that connects the polyvinyl alcohol (PVA) nodules, forming a single integrated piece. The foam bar contains multiple PVA nodules attached in a continuous row, which are molded together as a unit. The nodules are designed to provide the scrubbing action required for cleaning wafers and other delicate electronic components. The nodule bar is configured so that it can be easily inserted into the rail plates, which hold the nodules in place on the brush core. The nodules themselves are spongy and flexible, made from PVA to retain cleaning agents and provide gentle but effective scrubbing action. The design of the foam bar ensures that all nodules remain securely connected, preventing individual nodules from becoming dislodged during the high-speed rotation of the brush.

FIG. 7 presents a perspective view of the rail plate without the PVA nodule foam bar inserted. This figure shows the structure of the rail plate that is used to hold the foam bar in place once it is inserted. The rail plate has multiple openings or holes, which are aligned with the positions of the PVA nodules on the foam bar. These holes are precisely sized to tightly fit the nodules, securing them in place and preventing any movement or misalignment during the operation of the brush. The rail plate is designed to be mounted onto the core member of the cylindrical brush. Once the foam bar is inserted through the holes of the rail plate, the plate is then affixed to the core, locking the PVA nodules in place. The tight fit between the PVA nodules and the rail plate ensures that the nodules remain secure even during high-speed rotations. The precise engineering of the plate's holes allows for easy assembly, while also ensuring durability during use.

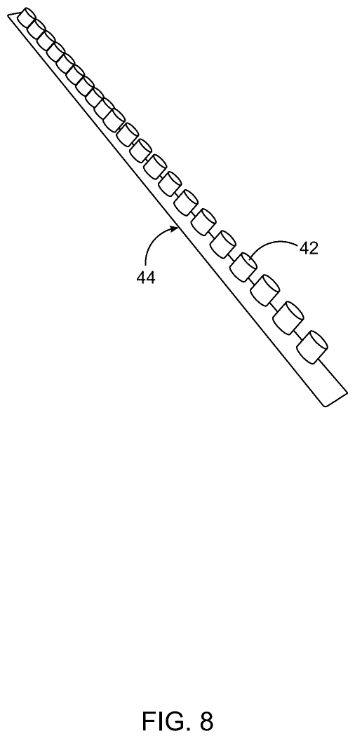

FIG. 8 shows the rail plate 24 in a complete assembled state. The internal crossbar in the proximal end hole prevents the PVA foam bar 44 from disengagement at the extreme ends since the ends of the foam bar 44 do not benefit from an adjoining neighboring PVA nodule 42 like all the others for security of fastening. This figure shows how the PVA nodule foam bars are inserted into the rail plates, and the rail plate is then secured to the core of the cylindrical brush. The PVA nodule foam bars have been inserted into the corresponding holes in the rail plate, ensuring a tight fit that holds the nodules securely in place. The foam bars, once installed, allow the PVA nodules to protrude from the plate, ready for cleaning action. Here, The rail plate 24 is shown as fully assembled, indicating that all components—including the nodules and the underlying plate—are correctly aligned and ready to be mounted onto the core of the brush. The design of the plate ensures that it accommodates the varying lengths of the PVA nodules as described in earlier figures, allowing the brush to conform to different gap sizes when applied at an angle to a wafer or other surface. The assembled view presented in FIG. 8 emphasizes the ease of assembly of the PVA nodules into the rail plates, while also showing how securely the components fit together to ensure consistent cleaning performance.

FIG. 9 shows a perspective view of the core member of the cleaning tool, onto which the assembled rail plates and PVA nodule foam bars are mounted. This figure illustrates the structure of the core, which is the central component of the cylindrical brush. The core member is the central cylinder or frame onto which the rail plates, holding the PVA nodules, are attached. It is typically designed to be mounted onto a rotating shaft, which drives the brush during the cleaning process. The core is shown with slots or grooves along its surface, into which the rail plates are fitted. These slots ensure that the rail plates are held firmly in place, preventing slippage or misalignment during operation. The core member may have a cylindrical or polygonal shape (such as a dodecagon), depending on the specific application, which ensures that the rail plates are aligned properly and securely attached. Openings are shown at the ends of the core member, where the brush will be attached to the cleaning machine's rotating shaft. The ends of the core are closed using end caps, which help secure the entire assembly and ensure stability during use. This figure highlights the structural integrity of the core member, which is critical for ensuring that the rail plates, and by extension the PVA nodules, remain securely attached during the cleaning process. The core's design ensures that the brush can operate at high speeds without the risk of dislodging the nodules or the rail plates.

As shown in FIG. 9 and FIG. 10, the core member has space for 12 rails and thus there is a total of 12 rows of PVA nodules 42 on the fully assembled core member 46. In other embodiments, any number of rows of nodules such as 10, 14, 16 are provided. Although the core member 46 may appear cylindrical, it can have any number of sides, however a dodecagon shaped core is preferred. FIG. 10 shows a perspective view of the core member 46 of the cleaning tool 20 with portions of the rail plate 24 inserted thereon and into which a row of PVA nodules 44 being inserted.

Continuing with FIG. 10, this figure illustrates the assembly process of the cylindrical brush, focusing on the integration of the PVA nodules and rail plates with the core member. The core member is shown with slots or grooves along its surface, into which the rail plates are being inserted. These slots are designed to hold the rail plates firmly in place, ensuring that they do not shift or become misaligned during operation. The PVA nodule foam bars, which contain a continuous row of nodules, are shown being inserted into the rail plates. The nodules pass through the holes in the rail plates, ensuring that they protrude from the brush surface, ready for cleaning action. The rail plates are affixed into the grooves of the core member in a precise, alternating arrangement. This ensures that the PVA nodules are aligned in a specific pattern, enhancing the brush's ability to clean surfaces at various angles and gap sizes. The core member is designed to accommodate multiple rail plates, allowing for a complete cylindrical assembly with rows of PVA nodules evenly distributed around the core. The figure shows how the assembly process is modular, allowing for easy installation of the foam bars and plates onto the core. The end portions of the core member, visible in the figure, include openings that are used to mount the cylindrical brush onto the rotating shaft of the cleaning machine. The core is designed for stability and strength, ensuring that it can withstand high-speed rotations without losing its structural integrity.

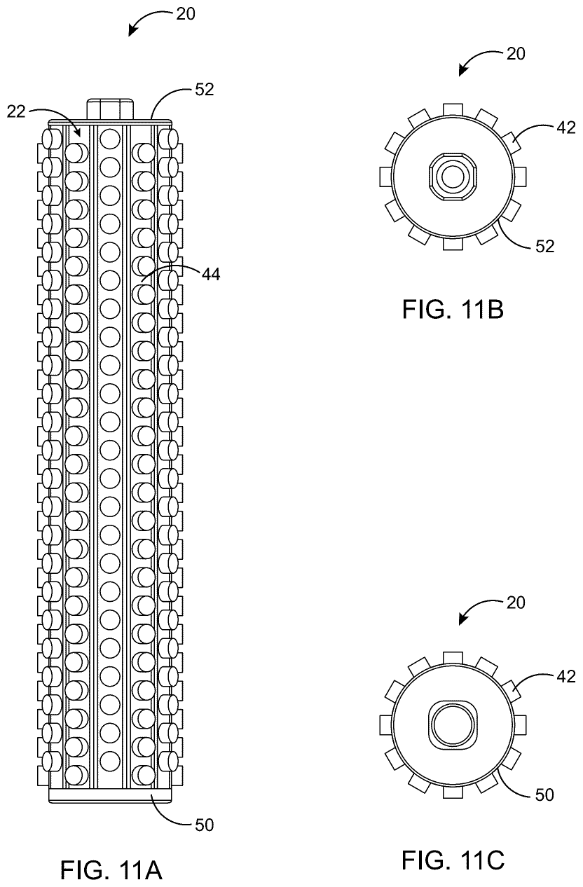

FIG. 11A shows a perspective view of the complete assembly of the cleaning tool 20 illustrating the cylindrical brush 22 and the plurality of PVC foam bars 44. FIG. 11B shows a top view of the cleaning tool 20 shown in FIG. 11A. FIG. 11C shows a rear view of the cleaning tool 20 shown in FIG. 11A. These figures show how the cylindrical brush and PVA foam bars are integrated to form the complete brush assembly. The multiple rows of PVA nodules are evenly distributed around the cylindrical core, with each row held securely by the rail plates that were inserted into the core member (as shown in previous figures). The PVA nodules are clearly visible, protruding from the brush and ready for contact with the surface to be cleaned (e.g., a wafer). These nodules are arranged in rows along the surface of the brush to ensure thorough cleaning. The end caps are attached to the ends of the cylindrical core, sealing the openings where the core attaches to the rotating shaft of the cleaning machine. The end caps ensure that the entire assembly remains securely in place during operation, preventing any dislodgement of the rail plates or PVA foam bars. The alternating arrangement of the rail plates can be observed, highlighting how the nodules are staggered to improve surface coverage and optimize cleaning efficiency.

FIG. 11B shows a top view of the fully assembled cleaning tool. This view provides a clearer look at the arrangement of the PVA nodule rows around the core and the distribution of the rail plates. From the top-down perspective, the symmetry of the brush design is evident, with the rows of PVA nodules evenly distributed along the surface of the cylindrical core. The alternating lengths of the nodules, as discussed in earlier figures, can be seen more clearly from this viewpoint. The core member is hidden beneath the rows of PVA nodules and rail plates, but the tight fit of the foam bars into the rail plates is visible, ensuring that the brush will maintain its structure and cleaning effectiveness during high-speed operation. The end caps are visible at both ends of the core, securing the rail plates and foam bars in place and preventing any movement or misalignment during operation. This figure emphasizes the structural stability and uniform distribution of the cleaning elements across the brush, showing how the brush is designed to ensure consistent cleaning coverage on all sides.

FIG. 11C provides a rear view of the fully assembled cleaning tool, offering another perspective on the arrangement of the brush components. From this viewpoint, the PVA nodule rows are again visible, showing how they are evenly spaced around the cylindrical core. The staggered placement of the nodules, which enhances the brush's ability to clean surfaces at different angles, is evident. The core member and the rail plates are secured tightly, with the end caps firmly attached at both ends of the core. These end caps help keep the entire assembly intact, ensuring the brush operates smoothly even under the stress of high-speed rotation. This rear view reinforces the modularity and stability of the cylindrical brush design. It highlights how the core, rail plates, and PVA nodules are all tightly integrated to form a durable cleaning tool capable of handling delicate cleaning tasks, such as wafer cleaning, without losing structural integrity.

The cylindrical brush 22 can be constructed in two ways. In conventional cleaning brushes, they are molded and cast through the plastic. For the preferred embodiment, the brush 22 can be either dovetailed into position and mechanically slid in like a disposable rail plate 24 as shown in the FIGS. 2-11, or the rail plate 24 can be affixed into place along the core member 46 using screws, glue, ultrasonic bonding or the like. In the second situation, the PVA nodules 42 need not be dovetail shaped and the assembly instead allows other shapes such as square and the like. In one method of the assembly, the PVA nodules 42 may be simply forced through the openings.

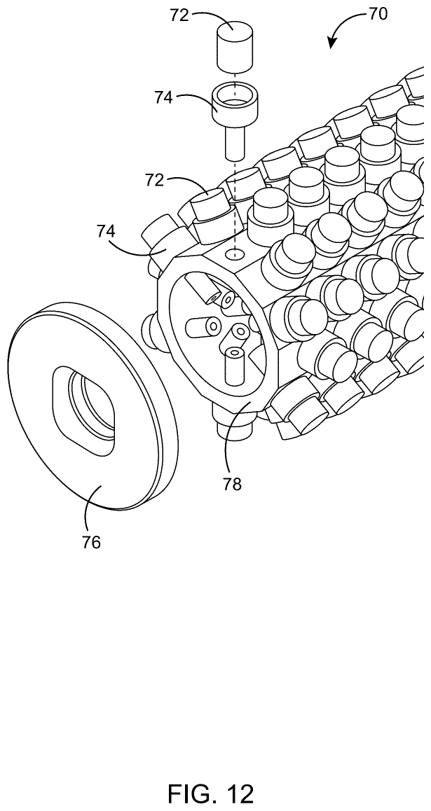

FIG. 12 shows an exploded view of another embodiment of the cylindrical brush 70. At the center of the assembly is the core member 78, which forms the backbone of the cylindrical brush. This core provides the structure onto which all other components are mounted. The core member is designed with slots or grooves along its surface to accommodate the attachment of holders for the PVA nodules. The PVA nodule 72 are the actual cleaning elements in the brush. In this embodiment, each nodule is separately attached to the core via a holder 74, instead of being part of a continuous foam bar as shown in previous figures. The individual nodule design offers flexibility in assembling brushes with customized nodule configurations to address specific cleaning needs. The holder 74 serves as an intermediary component, ensuring that the PVA nodules are securely mounted to the core. The holders can be press-fitted, threaded, or ultrasonically welded onto the core, depending on the application requirements. This design allows for easy replacement of individual nodules if needed, enhancing the modularity and maintainability of the brush. The end caps 76 are shown at either end of the core member. These caps seal the ends of the core, securing all components in place and preventing the holders or PVA nodules from shifting during operation. The end caps also serve to attach the brush to the rotating shaft of the cleaning machine, providing stability during use.

In summary, each PVA nodule 72 is separately attached to the core member 78. This is done by first casing a PVA nodule 72 into a holder 74 that is then attached to the core member 78. The holder 74 can be attached to the core member 78 via a thread, press fit, ultrasonic weld, snap, glue or other suitable attachment means. The holder 74 extends radially inwardly thereby filling the void space within the core member 78. The cylindrical brush 70 includes a pair of end caps 76.

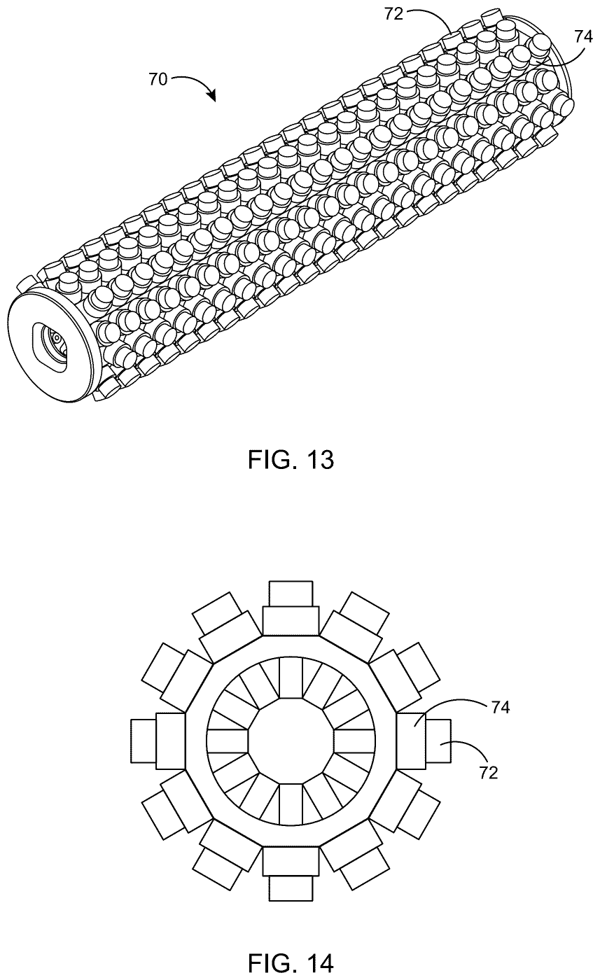

FIG. 13 depicts a perspective view of the fully assembled brush 70 shown in FIG. 12, where each PVA nodule is individually attached to the core member via a holder. The cylindrical core 78 is at the center of the assembly, with holders attached along its surface. The core provides the structural support for the brush and serves as the backbone onto which all the cleaning components are attached. The PVA nodules 72 are shown in their final configuration, each securely held in place by the holders 74. The nodules protrude from the surface of the brush, designed to engage with and clean the surface of a wafer or other electronic component. Each holder 74 secures an individual PVA nodule to the core. The holders are shown firmly affixed to the core, ensuring that the nodules do not dislodge during operation. The holders provide flexibility in assembling and maintaining the brush, as each nodule can be replaced independently if necessary. The end caps 76 are fitted at either end of the core member. These caps ensure the structural stability of the brush and help secure the entire assembly in place on the rotating shaft of the cleaning machine. The end caps also contribute to the alignment and positioning of the holders and PVA nodules.

In this fully assembled view, the brush is ready for use in wafer cleaning or other precision cleaning applications. The modular design, with individually mounted nodules, offers the flexibility to replace nodules as needed, ensuring long-term durability and adaptability to different cleaning tasks.

FIG. 14 provides a rear view of the cylindrical brush shown in FIG. 13, but without the end caps. This view offers a clearer look at the core member and how the holders are mounted onto the core. The rear view exposes the core member in greater detail. Without the end caps in place, the openings at the ends of the core are visible. These openings are used to attach the brush to the cleaning machine's rotating shaft. The holders 74 are shown mounted along the length of the core, evenly distributed around its circumference. Each holder is securely attached to the core, ensuring that the PVA nodules remain firmly in place during high-speed operation. The holders are designed to maintain the tight fit needed to prevent any dislodgement or movement during use. The PVA nodules 72 are visible from this angle, showing how they protrude from the holders and are positioned to engage with the surface being cleaned. The even distribution of the nodules around the core ensures comprehensive surface coverage during cleaning. By removing the end caps in this view, FIG. 14 offers a clearer understanding of the mounting mechanism used to attach the holders to the core. This view highlights the secure attachment of the holders, ensuring that the entire assembly remains stable during operation.

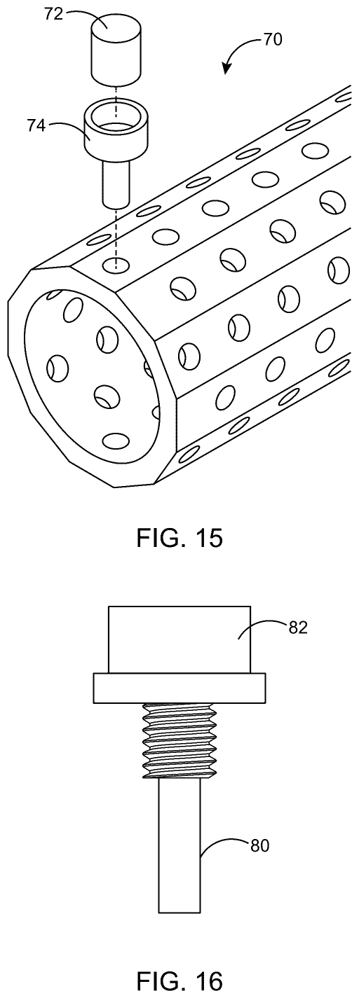

FIG. 15 depicts an exploded view of the cylindrical brush 70 during assembly according to another embodiment shown in FIG. 12. This figure gives a detailed breakdown of how the PVA nodules, holders, core member, and end caps are organized and how they come together to form the completed cylindrical brush. The PVA nodules 72 are the primary cleaning elements of the brush, designed to scrub surfaces like wafers during the cleaning process. In this embodiment, each nodule is an individual unit that will be mounted to the core via its respective holder. This modular approach allows for customization of nodule types, shapes, and sizes, depending on the cleaning requirements. Each holder 74 is designed to encase a single PVA nodule. The holder provides the means for securely attaching the nodule to the core member 78. The holders are shown as cylindrical or tubular structures, with openings that house the PVA nodules. These holders act as intermediaries between the nodules and the core, ensuring that the nodules remain securely fastened during high-speed rotations. The holders are mounted into the slots or grooves in the core member. This method of attachment allows for easy installation and replacement of individual nodules as needed.

The core member 78 serves as the central axis of the cylindrical brush. It has several slots or grooves along its surface, into which the holders (containing the PVA nodules) are inserted. The core is shown as having a cylindrical or polygonal shape (such as dodecagonal), which helps maintain alignment and secure attachment of the holders. The slots or grooves along the core's surface ensure that each holder is placed at the correct angle and position, maintaining an even distribution of nodules around the brush. The end caps 76 are positioned at both ends of the core member to seal the brush assembly and hold the components securely in place. These caps also provide the mounting points for attaching the brush to the rotating shaft of the cleaning machine. The caps ensure that the holders and PVA nodules remain in place during operation and prevent any movement or dislodging caused by the rotational forces.

As part of the assembly process, this exploded view shows each component separately to illustrate how the modular system works. The PVA nodules are first inserted into the holders, which are then mounted into the grooves of the core. Once the holders are secured to the core, the end caps are placed at both ends to complete the assembly, ensuring that the entire structure is locked in place and ready for use. This design allows for easy assembly and disassembly, making it simple to replace worn-out nodules or modify the brush with different nodule configurations.

FIG. 16 shows another embodiment of the holder 80 and the PVA nodule 82 wherein the holder 80 has a short stem and the PVA nodule has a long stem. This exploded view highlights the modular design of this alternative embodiment, where each PVA nodule is individually mounted to the core via a holder. In this embodiment, the PVA nodule has a longer stem compared to previous designs. The elongated stem allows for a deeper insertion into the holder, ensuring a stronger and more secure attachment to the core. The nodule itself retains the sponge-like properties typical of PVA material, ideal for absorbing cleaning agents and gently scrubbing delicate surfaces, such as wafers. The extended stem provides additional stability during high-speed rotation, minimizing the risk of the nodule detaching from the holder. This configuration allows for greater customization of the brush, as nodules of different shapes, sizes, and materials can be used to tailor the brush to specific cleaning tasks.

This alternative design with the long-stemmed PVA nodule and shorter holder is particularly well-suited for applications where the brush needs to maintain its integrity under challenging conditions, such as high-speed rotations or when used in harsh environments. The configuration allows for high-density nodule placement, making it ideal for cleaning tasks that require thorough and precise scrubbing of delicate surfaces, such as semiconductor wafers or other electronic components.

Returning to FIG. 2 and FIG. 3, the cylindrical brush 22 includes certain advantages over the cleaning brush shown in FIG. 1A and FIG. 1B. For instance, the cylindrical brush 22 has less weight that causes less wear on machinery. Further, with respect to the environment, the brush 22 has 90% less PVA. The cylindrical brush 22 also exhibits decreased break-in time, zero de-molding in the manufacturing process, releases fewer particles, decreased fab water usage, decreased disposable waste and overall increased efficiency in cleaning of the wafer.

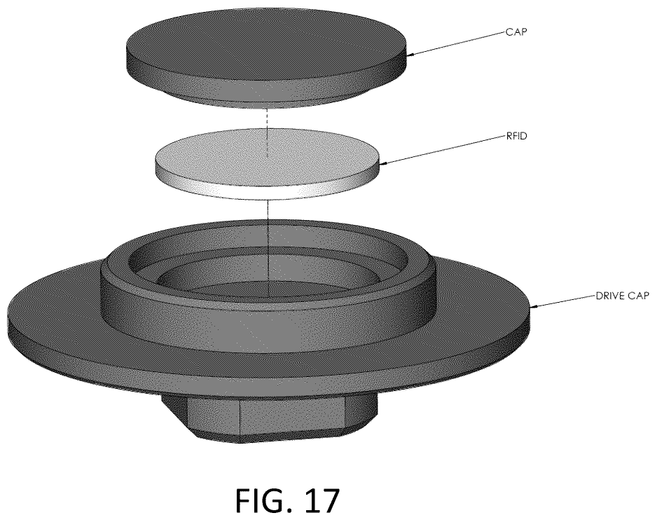

Turning now to FIG. 17, an RFID tag embedded in the drive cap of the device is shown in perspective view. Here, The RFID tag is embedded within the drive cap at one end of the cylindrical brush. This RFID system allows for wireless tracking of the brush, providing information such as the number of uses, wear levels, and performance metrics. The water-scaling cap and drive cap may be assembled with an interference fit or via ultrasonic welding, which along with a cyclohexanone solvent, provides a water-sealed assembly for the RFID tag. The drive cap itself serves as the housing for the RFID system. It is located at the end of the cylindrical brush and is designed to be durable and resistant to wear. The drive cap not only holds the RFID tag in place but also serves its primary function of securing the cylindrical brush to the cleaning machine's rotating shaft.

The RFID tag is sealed inside the cap to protect it from water, chemicals, and debris that could interfere with its functionality. This ensures that the RFID system remains operational even in harsh industrial environments. The RFID tag can be read remotely by an RFID reader, allowing operators to monitor the status of the brush in real-time without the need for manual inspections. This feature is particularly useful in environments where frequent maintenance and monitoring are necessary to ensure optimal performance. Furthermore, in environments where high-precision cleaning of wafers is critical, the RFID system can provide valuable data to ensure that brushes are maintained or replaced at the right time, preventing contamination and ensuring product quality. In larger cleaning systems where multiple brushes are in operation, RFID tracking allows for more efficient management of brush inventories and maintenance schedules, ensuring that all brushes are functioning optimally.

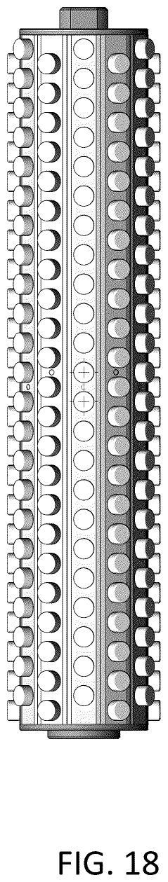

Turning next to FIG. 18, a typical brush nodule layout is presented where the nodules are spaced evenly from end to end longitudinally down the brush. The spacing between each nodule is equal across the entire length of the cylindrical brush, ensuring that the brush applies even pressure on the surface being cleaned. This layout is ideal for surfaces that are flat or require uniform cleaning coverage. The uniform distribution of the nodules ensures that the entire surface of the brush is engaged in the cleaning process. Every nodule is designed to make contact with the surface simultaneously, providing a consistent scrubbing action across the entire area. This configuration is commonly used in standard cleaning applications, where the surface being cleaned is flat or uniformly shaped. It provides efficient cleaning without any need for specialized nodule arrangements. It is ideal for wafer cleaning or similar tasks where the surface to be cleaned is uniform in shape, ensuring that the entire surface is evenly scrubbed during each rotation of the brush. This symmetrical design ensures that no part of the brush is overworked or underused, reducing wear on specific areas and extending the overall lifespan of the brush.

Benefits of the evenly spaced design: Consistent Cleaning: The even spacing of the nodules ensures that the surface being cleaned receives uniform contact throughout the entire cleaning process. Balanced Brush Operation: The brush's weight and contact points are evenly distributed, ensuring smooth and balanced operation during high-speed rotations. Reduced Wear and Tear: The uniformity of the nodule arrangement prevents excessive wear on any one part of the brush, extending its lifespan and reducing maintenance costs.

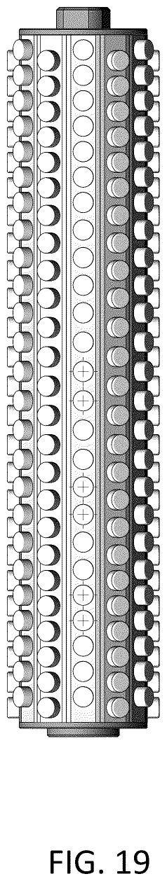

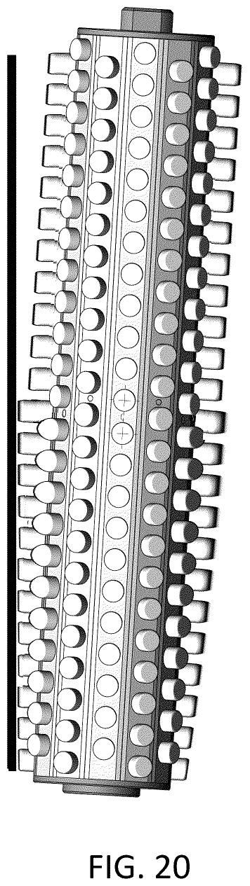

In contrast to FIG. 18, FIG. 19 shows an alternative embodiment of the invention where the nodules need not be evenly spaced from end to end longitudinally down the brush. This figure highlights the use of variable spacing between the nodules, offering a more specialized cleaning tool designed to adapt to different cleaning needs. Instead, the spacing between the nodules varies along the longitudinal axis, allowing the brush to be tailored for specific cleaning tasks. The density of the nodules may increase or decrease along the brush's length, depending on the requirements of the cleaning process. For example, there may be more nodules concentrated at the ends of the brush and fewer nodules in the middle, or vice versa, depending on the desired cleaning effect.

This configuration is used when a different level of cleaning intensity is required along different parts of the brush. For example, more nodules at the ends of the brush might provide greater cleaning power at those points, while fewer nodules in the center reduce friction or allow for gentler cleaning. This design can also accommodate non-uniform surfaces or objects that require variable pressure during the cleaning process. By adjusting the nodule spacing, the brush can apply different levels of scrubbing action to specific parts of the surface being cleaned.

Benefits of the unevenly spaced nodule design: Targeted Cleaning: The variable spacing allows for customized cleaning based on the specific requirements of the surface being cleaned. The operator can choose where to concentrate the cleaning action. Adaptability: This design allows the brush to be adapted to different cleaning applications, making it suitable for a wide range of industrial tasks, particularly where precision and variation in cleaning are required. Optimized Performance: By concentrating the nodules where they are needed most, this configuration optimizes the cleaning process, ensuring that critical areas receive more attention while other areas are cleaned more gently. This unevenly spaced nodule configuration offers greater flexibility and control over the cleaning process, allowing for specialized applications where a standard brush might not be effective. It is particularly useful in industries requiring precision cleaning or dealing with irregularly shaped objects.

The preferred cylindrical brush 22 provides benefits to the end users of the product which are typically fabs for chip (wafer) production. Such benefits may include availability of the PVA nodule design from round to limitless forms of designs such as triple edge and angle edge as shown best in FIGS. 4A-4C.

With respect to the particles, a normal brush after hours of wash (a treatment bath) includes about 2,500 particles. In contrast, in the preferred embodiment, in less than 20 minutes the cylindrical brush 22 has been shown to release fewer than 50 particles. Certain benefits of the cylindrical brush 22 specific to PVA manufacturing include 76% less raw materials to make the PVA brushes, 40% less shipping weight, 98% production yields compared to an average 76%, the elimination of expensive mold cleaning in process, 78% less toxic chemicals in manufacturing PVA thereby making it better for the environment and eco-system, less of a cure time compared to 16 hours of oven time and electricity to cure in ovens, full injection molded rails, full automation in the process of manufacturing compared to the manual work being performed at present. Further, the preferred cylindrical brush 22 enables customers to develop, test and produce PVA brushes with unique nodule contours. The cylindrical brush 22 has better water to nodule positioning to enhance cross-contaminant purging. Here, water flows through the nodules 42 making direct contact with wafer. The water rinses the nodules 42 to prevent re-contamination on subsequent wafer.

Other advantages of the preferred cylindrical cleaning brush 22 include a reduction in break in time of 95%, 100% of the water flows through the brush 22 to the non-dual nodule (which decreases overall water usage for the end user). To obtain the same efficiency of the preferred cylindrical brush, the fab would use 90% less water flowing through the cleaning brush 22. Finally, less weight of the preferred cleaning brush 22 saves on machine wear parts (i.e., bearings, motors).

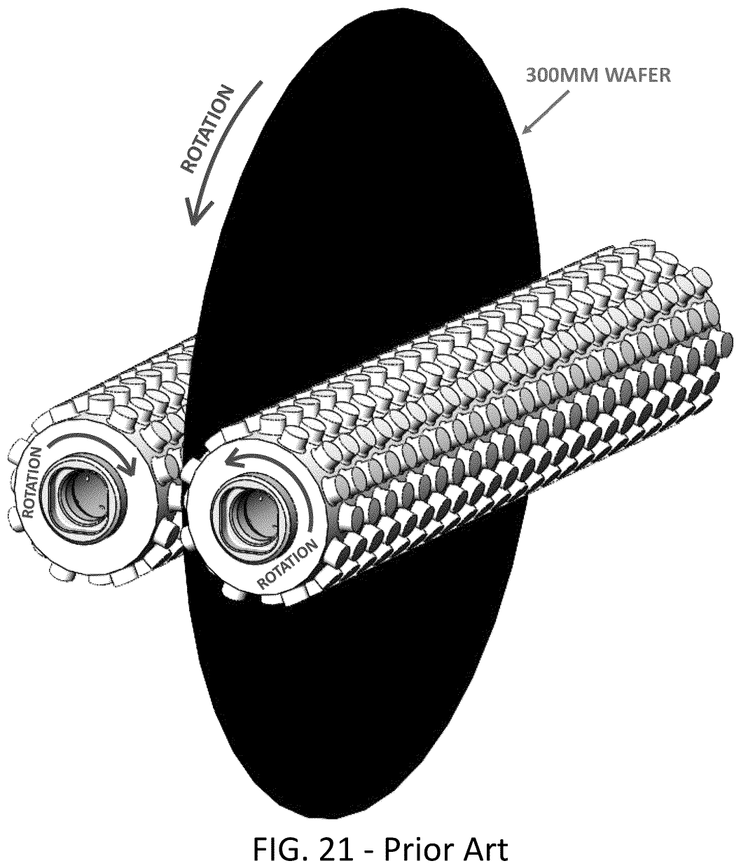

In other embodiments, the brush has uneven nodule lengths as is shown in FIG. 20. Here, the brush has uneven brush lengths along one side of the brush such that when the brush is placed against a circular wafer at an angle, the brush lengths along one half of the circular wafer accommodate the changing gap size due to the angle. Said again, it a brushing device characterized by varying nodule lengths on one side, designed to conform to the changing gap size when positioned against a circular wafer at an angle. Said again, it is an apparatus featuring nodule variations along a specific side, intended to adapt to fluctuations in gap size when the apparatus is inclined against a circular wafer. Said again, it is a brush structure with non-uniform bristle lengths on one edge, specifically engineered to adjust to alterations in gap size resulting from the angled placement against a circular wafer. Said again, it is designed to effectively manage the changing gap dimensions caused by the inclination of the brush against a circular wafer. Said again, it is a specialized brush assembly, comprising uneven bristle lengths on a designated side to address variations in gap size during angled contact with a circular wafer. FIG. 21 is a prior art image showing the previous means for using brushes to impart rotation to a wafer.

Benefits of the Invention—The invention presents several key benefits over conventional cleaning brushes:

Enhanced Cleaning Efficiency: The brush's varying nodule lengths and spacing enable it to adapt to different gap sizes and surface contours, ensuring thorough cleaning across the entire surface, even when applied at an angle. The precise arrangement of nodules ensures optimal surface contact, leading to more effective scrubbing without causing surface damage.

Reduced Material Use and Environmental Impact: By optimizing the nodule arrangement, the brush uses less PVA material, lowering production costs and reducing the overall environmental footprint. The brush is lighter in weight, reducing wear on cleaning machinery and further decreasing energy consumption during operation.

Customizability: The brush is highly customizable, with the ability to adjust the length and arrangement of nodules for specific cleaning tasks. Whether a high-density nodule configuration is needed for aggressive cleaning or a lighter nodule arrangement for delicate surfaces, the modular design allows for easy adaptation. Different shapes and sizes of nodules can be used depending on the requirements of the application, making the brush versatile across multiple industries.

Durability and Long-Lasting Performance: The secure attachment system, including the use of holders and end caps, ensures that the nodules stay firmly in place during high-speed cleaning operations, preventing any loss of performance due to detachment or misalignment. The robust modular design reduces wear and tear, ensuring that the brush remains operational for longer periods and requiring less frequent replacement.

Real-Time Monitoring: The integration of RFID technology provides significant operational advantages by enabling real-time tracking of the brush's usage and condition.

Future alternative embodiments of the invention could employ greater nodule material variation: While the present invention currently focuses on PVA nodules, future iterations could incorporate other materials, such as silicone or rubber, to suit different cleaning environments. These materials could provide greater flexibility, heat resistance, or chemical compatibility for specialized cleaning applications. The cylindrical brush design could be adapted for use in automotive, aerospace, and pharmaceutical industries, where precision cleaning of delicate parts and components is critical to maintaining quality and performance.

In one further embodiment, a method of cleaning a surface using a cylindrical brush is provided, the method comprising rotating the cylindrical brush mounted on a shaft, the cylindrical brush having polyvinyl alcohol (PVA) nodules arranged along its surface; applying the brush to a surface, such as a semiconductor wafer, such that the PVA nodules contact the surface; allowing the PVA nodules to absorb and release cleaning agents while scrubbing the surface; and varying the pressure and angle of the brush to adapt to different gap sizes, where the PVA nodules have varying lengths to conform to the surface being cleaned.

The present invention represents a significant advancement in the design and functionality of cylindrical cleaning brushes. The use of variable nodule lengths and arrangements, combined with the modular, replaceable components, provides a highly efficient, customizable, and long-lasting cleaning tool suitable for a wide range of precision cleaning applications. The brush's ability to adapt to various surface geometries, combined with its lightweight design and reduced material usage, ensures that it offers both operational and environmental benefits.

The foregoing description of the preferred embodiment of the present invention has been presented for the purpose of illustration and description. It is not intended to be exhaustive or to limit the invention to the precise form disclosed. Many modifications and variations are possible in light of the above teachings. It is intended that the scope of the present invention to not be limited by this detailed description, but by the claims and the equivalents to the claims appended hereto.

1. A cylindrical cleaning brush for cleaning electronic components, comprising:
a core member having a cylindrical or polygonal shape with a plurality of longitudinal slots;
a plurality of polyvinyl alcohol (PVA) nodules arranged along the outer surface of the core member;
a plurality of holders, each holder configured to receive and secure at least one PVA nodule;
the holders being mounted into the longitudinal slots of the core member, securing the PVA nodules in place;
end caps attached to both ends of the core member, sealing the assembly and securing the holders in place;
wherein the PVA nodules are spaced evenly along the length of the core member, providing uniform cleaning coverage.

2. The cylindrical cleaning brush of claim 1, wherein the PVA nodules have varying lengths along at least one side of the brush, allowing the brush to adapt to different gap sizes when applied at an angle to a circular surface.

3. The cylindrical cleaning brush of claim 2, wherein the PVA nodules have a longer stem portion for deeper insertion into the holders, ensuring a more secure attachment to the core member.

4. The cylindrical cleaning brush of claim 1, wherein the holders are attached to the core member through interference fitting, ultrasonic welding, or mechanical fasteners, ensuring that the PVA nodules remain securely attached during high-speed cleaning operations.

5. The cylindrical cleaning brush of claim 1, wherein the PVA nodules are arranged in unevenly spaced rows along the length of the core member, allowing for variable cleaning intensity along different sections of the brush.

6. The cylindrical cleaning brush of claim 1, wherein the PVA nodules are mounted in a zig-zag pattern along the core member, enhancing the scrubbing action and improving cleaning efficiency on non-uniform surfaces.

7. The cylindrical cleaning brush of claim 1, wherein the core member includes a dodecagonal cross-section, allowing for precise positioning of the holders and nodules along the surface.

8. The cylindrical cleaning brush of claim 1, further comprising a plurality of rail plates attached to the core member, the rail plates having holes through which the PVA nodules are inserted, providing additional support and alignment for the nodules.

9. A brush device for cleaning a circular wafer, comprising:
a core member;
a plurality of nodules positioned along the surface of the core member, the nodules having varying lengths along one side of the brush;
wherein the varying lengths of the nodules are configured to accommodate a changing gap size when the brush is applied at an angle to the surface of the circular wafer, ensuring consistent contact with the wafer.

10. The brush device of claim 9, wherein the nodules are made from polyvinyl alcohol (PVA) material, allowing the nodules to absorb and release cleaning agents while scrubbing the wafer surface.

11. The brush device of claim 9, wherein the core member is cylindrical, and the nodules are positioned in rows along the longitudinal axis of the core member, with varying nodule lengths in each row to accommodate angled cleaning.

12. A cylindrical brush assembly for wafer cleaning, comprising:
a core member with a longitudinal axis;
a plurality of bristles attached to the core member, the bristles having non-uniform lengths along one side of the brush;
a plurality of holders securing the bristles to the core member, wherein the non-uniform lengths of the bristles are adapted to accommodate a variable gap size when the brush is positioned at an angle relative to the wafer surface.

13. The cylindrical brush assembly of claim 12, wherein the holders are modular, allowing for the individual replacement of bristles with different lengths or materials as needed for specific cleaning applications.

14. The cylindrical brush assembly of claim 12, wherein the bristles are arranged in an alternating pattern along the longitudinal axis of the core member, optimizing the scrubbing action for surfaces with varying contours.

15. A method of cleaning a circular wafer, comprising:
providing a brush having a plurality of nodules with varying lengths along one side;
rotating the brush about its axis while positioning it at an angle relative to the wafer;
adjusting the contact of the varying length nodules to accommodate the changing gap size created by the angled position of the brush against the circular wafer surface;
scrubbing the wafer with the nodules to remove contaminants while maintaining consistent pressure across the surface.

16. The method of cleaning a circular wafer of claim 15, further comprising the step of applying a liquid cleaning agent to the wafer surface, allowing the polyvinyl alcohol (PVA) nodules to absorb the liquid and release it during the cleaning process.

17. The method of cleaning a circular wafer of claim 15, wherein the rotation speed of the brush is adjusted based on the angle of contact between the brush and the wafer, optimizing the cleaning efficiency across the entire surface.

18. The wafer cleaning device of claim 15, wherein the nodules are arranged in unevenly spaced rows along the longitudinal axis of the core member, with greater nodule density at the ends of the brush for increased cleaning power in those areas.

19. The method of cleaning a circular wafer of claim 15, wherein the brush is moved across the surface of the wafer in a radial pattern, ensuring that the entire surface is uniformly scrubbed by the varying length nodules.

20. A method of assembling a cylindrical cleaning brush, comprising:
providing a core member with a plurality of longitudinal slots;
inserting a plurality of holders into the longitudinal slots of the core member;
inserting polyvinyl alcohol (PVA) nodules into the holders, wherein each holder is configured to receive and secure the PVA nodules;
attaching end caps to both ends of the core member, securing the holders and PVA nodules in place;
arranging the PVA nodules in a configuration that provides uniform or variable cleaning coverage along the length of the core member.

21. The method of claim 20, wherein the PVA nodules are inserted into the holders with varying lengths, allowing the brush to adapt to different gap sizes when applied at an angle to a circular surface.

22. The method of claim 20, further comprising the step of arranging the PVA nodules in unevenly spaced rows along the core member, thereby allowing for variable cleaning intensity across different sections of the brush.

23. The method of claim 20, further comprising the step of securing the holders to the core member using ultrasonic welding, mechanical fasteners, or interference fitting, ensuring a tight and durable connection between the holders and the core.

24. The method of claim 20, further comprising the step of attaching a plurality of rail plates to the core member, the rail plates having holes through which the PVA nodules are inserted, providing additional structural support for the PVA nodules.
